(19) United States
(12) Patent Application Publication
(10) Pub. No.: US 2024/0372330 A1
(43) Pub. Date: Nov. 7, 2024

(54) LASER DEVICE

(71) Applicants: TRUMPF Photonic Components GmbH, Ulm (DE); ifm electronic GmbH, Essen (DE); pmdtechnologies ag, Siegen (DE)

(72) Inventors: Holger Joachim Moench, BM Vaals (NL); Stephan Gronenborn, Aachen (DE); Samuel Freywald, Kreuztal (DE); Thomas Dietz, Koenigsfeld im Schwarzwald (DE)

(21) Appl. No.: 18/741,655

(22) Filed: Jun. 12, 2024

Related U.S. Application Data
(63) Continuation of application No. PCT/EP2022/086071, filed on Dec. 15, 2022.

(30) Foreign Application Priority Data
Dec. 17, 2021 (DE) 10 2021 133 748.8

(51) Int. Cl. H01S 5/183; H01S 5/42

(52) U.S. Cl. CPC H01S 5/18388; H01S 5/423

(57) ABSTRACT

A laser device includes a semiconductor laser component. The semiconductor laser component includes a laser array. The laser array includes a plurality of semiconductor lasers emitting a laser light vertically. The laser device further includes an optics device. The optics device includes at least a second optics element, and a first optics element arranged between the second optics element and the laser array along an optical axis. The optics device is configured for expanding the laser light emitted from the semiconductor lasers, collimating the expanded laser light, and for shaping a beam profile of the collimated laser light.

### CROSS REFERENCE TO RELATED APPLICATIONS

This application is a continuation of International Application No. PCT/EP2022/086071 (WO 2023/111137 A1), filed on Dec. 15, 2022, and claims benefit to German Patent Application No. DE 10 2021 133 748.8, filed on Dec. 17, 2021. The aforementioned applications are hereby incorporated by reference herein.

### FIELD

Embodiments of the present invention relate to a laser device having a semiconductor laser component.

### BACKGROUND

Due to the increase of the power densities of vertically emitting semiconductor lasers, so-called VCSELs (vertical cavity surface emitting lasers) in recent years, it is possible to emit laser light with a maximum power from a chip that reaches the limits of laser safety. Thereby, for laser safety for lasers in the region of the visible and near-infrared spectrum (400 nm to 1050 nm) the size of the apparent source is important, if the laser source is an extended source (see IEC 60825-1:2014 section 4.3.d). The allowed laser power increases linearly with the parameter C6 which increases linearly with the averaged edge length of the apparent source size alpha (see IEC 60825-1:2014, section 4.3.d) of the laser source, if this lies in the region of 1.5 mrad to 100 mrad. Below 1.5 mrad, the laser is considered a point source and the allowed laser power no longer depends on the laser size. It is important to note that without optics the emission area on the semiconductor laser chip determines the apparent source size, but after a perfect diffuser the illuminated area of this diffuser determines the source size. For increasing laser safety, on the on hand the emission area of the laser chip can thus be increased, but on the other hand also the illuminated area on the beam-shaping element can be increased if it fulfills the properties of the perfect diffuser.

### SUMMARY

Embodiments of the present invention provide a laser device. The laser device includes a semiconductor laser component. The semiconductor laser component includes a laser array. The laser array includes a plurality of semiconductor lasers emitting a laser light vertically. The laser device further includes an optics device. The optics device includes at least a second optics element, and a first optics element arranged between the second optics element and the laser array along an optical axis. The optics device is configured for expanding the laser light emitted from the semiconductor lasers, collimating the expanded laser light, and for shaping a beam profile of the collimated laser light.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a laser device having an optical system comprising three optics elements according to some embodiments;

FIG. 2 illustrates a laser device having an optics device comprising a Fresnel lens according to some embodiments; and

FIG. 3 illustrates a laser device having an optics device comprising two optics elements according to some embodiments.

### DETAILED DESCRIPTION

Embodiments of the invention provide a laser device whose emitted laser light is with respect to its power within the limits of the laser safety regulations.

According to some embodiments, a laser device has a semiconductor laser component comprising a laser array comprising a plurality of semiconductor lasers emitting a laser light vertically, and having an optics device comprising at least a second optics element and a first optics element arranged between the second optics element and the laser array, which are arranged along an optical axis, wherein the optics device is configured for expanding the laser light emitted from the semiconductor lasers, for collimating the laser light and for shaping the beam profile of the collimated laser light.

The laser light propagates along the optical axis. The optical axis can coincide with a symmetry axis of the laser array and/or the optical axes of the optics elements. The individual semiconductor lasers each emit their own laser light, which at the latest after passing through all the optics elements superimposes and comprises in particular in the far field a homogeneous light intensity transverse to the optical axis. The shaping of the laser light by the optics device can be achieved by a scattering effect and/or by a superposition of laser light from different semiconductor lasers of the laser array, e.g. by refraction at a lens array or diffraction at a diffractive optical element. Here, each solid angle area of the shaped laser light is illuminated from many distributed areas within the illuminated area of the optics shaping the beam and the conditions of the standard IEC 60825-1:2014 4.3.d are met for all solid angles and the entire illuminated area and all sub-areas. In the preferred embodiment, the entire illuminated area illuminates every solid angle of the shaped laser light (perfect diffuser).

By using the optics device, the size of the source, which emits the laser light in terms of the laser safety regulations, can be increased independently of the actual size of the laser array. Thereby, the size of the optics elements can be used to comply with the limits of the laser safety regulations instead of enlarging the laser array. This is possible because the effective emission area is defined by the with respect to the optical axis outermost optics element, through which the laser light passes last and according to the description provided above is considered as a new apparent source according to IEC 60825-2:2014. Finally, by using the three optics elements, safe compliance with the laser safety regulations, decoupled from the temperature-related power limitation, can be ensured.

In particular, such laser devices can be used to illuminate a rectangular field of view of a camera with laser light.

It is preferred that laser light emanating from at least two locations of an illuminated area, which is generated by the laser light at an optics element of the optics device provided for shaping, is directed onto at least one solid angle range of an illuminated area outside the optics device, such that the conditions of the standard IEC 60825-1:2014 4.3.d are fulfilled for all solid angles. Hereby, several locations of the illuminated area can illuminate a location specified by the solid angle.

Advantageously, the first optics element can be a scattering lens which with respect to the optical axis of the laser light completely covers the entire laser array of the semiconductor component. This ensures an efficient utilization of the entire emitted laser light.

In a particular embodiment, it is provided that the first optics element expands the laser light such that a half maximum (half-value) angle of the laser light of all semiconductor lasers is more than 10°. This thereby enables a divergence of the laser light that goes beyond the initial divergence of the laser light generated by the configuration of the semiconductor laser without optics elements.

Preferably, the first optics element is formed integrally with the semiconductor component. Thereby a highly integrated design of the laser device can be achieved. In particular, this is the case if the first optics element is made of the same material as portions of the semiconductor component. For example, the material of a mirror portion or the material of the semiconductor substrate can serve as the basis for the first optics element.

In particular, the first optics element can comprise a lens array of refractive lenses, each having a symmetry axis, which is offset with respect to normal axes of the semiconductor lasers, wherein the symmetry axes and the normal axes are oriented parallel to the optical axis. The normal axes are located centrally at an emission region of the respective semiconductor laser, wherein the normal axes are oriented perpendicular to a surface of the respective semiconductor laser in which the emission region is provided. The laser light propagates along the emission area, wherein preferably a respective light cone is provided symmetrically around the normal axis.

In particular, it is provided that the second optics element is a collimating (converging) lens that generates a half-maximum (half-value) angle of the laser light of at most 10°. This enables collimation of the laser light, wherein the collimated laser light diverges by at most 10°. To illuminate a camera's field of view, it is advantageous if the input divergence into the optics element, which is to form the beam according to the camera's field of view, is as small as possible. This minimizes or avoids smearing of the desired profile and increases the intensity density in the camera's field of view.

It is preferred that the second optics element is configured as a Fresnel lens, a diffractive optical element and/or an optics element comprising an optical metamaterial.

The second optics element can comprise an element portion for collimating and an element portion for shaping the laser light on a common side. Alternatively or in addition, the second optics element can comprise an element portion for collimating on a first side and an element portion for shaping the laser light on a second side or the second optics element. This achieves a high level of functional integration in the second optics element.

In a further refinement, it is provided that the optics device comprises a third optics element, which is configured for shaping the collimated laser light, wherein the second optics element is preferably only configured for collimating the laser light. In this way, individual optics elements can be used which are manufactured easily and precisely.

It is advantageous if an illuminated area at the third optics element comprises a two to five times greater side length than the laser array. The illuminated area at the third optics element provides the effective source, which is decisive for compliance with the laser light regulations.

To allow an efficient use of the laser device in the field of camera applications, the third optics element shapes the laser light such that it comprises an aligned transversely to the optical axis rectangular cross-section. Hereby a rectangular field of view of the camera can be illuminated in a conformal manner.

In order to for example illuminate a camera's field of view with as homogeneous a light intensity as possible, the third optics element can comprise a lens array, a diffractive optical element and/or an optics element comprising an optical metamaterial.

The laser light emerging from the optics device has a cross-section aligned perpendicular to the optical axis, which comprises at a distance of at least one millimeter a two to five times greater side length than the laser array. Hereby a safe laser device is provided.

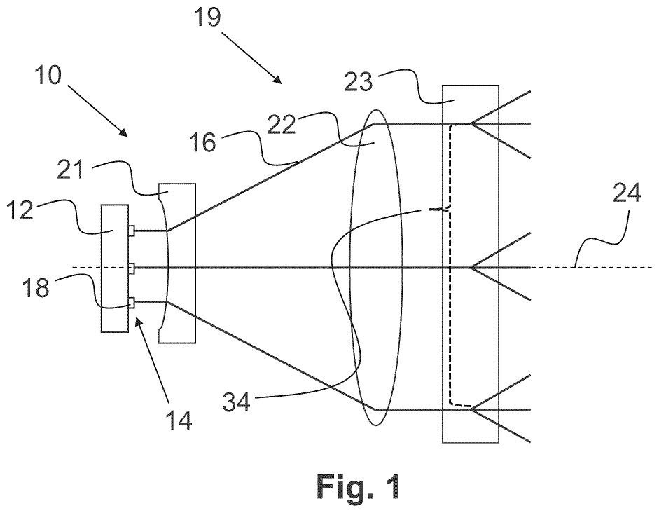

FIGS. 1 to 3 illustrate exemplary embodiments of a laser device 10 having a semiconductor laser component 12. The semiconductor laser component 12 comprises a laser array 14 comprising a plurality of semiconductor lasers 18 emitting a laser light 16 vertically. The laser array 14 is arranged on a side of the semiconductor laser component 12 that faces an optics device 19. The semiconductor lasers 18 are preferably arranged along a plane.

The semiconductor lasers are surface-emitting VCSELs (vertical cavity surface emitting lasers) comprising a layered structure. The optical axis 24 is oriented perpendicular to the layers on which the layered structure is based. The laser light 16 emerging from the semiconductor lasers 18 diverges in the far field with a full angle of approximately 10° to 20°, determined according to the second moment method of intensity distribution.

The optics device 19 comprises optics elements 21, 22, 23 that are arranged along an optical axis 24. The optical axis 24 is oriented perpendicular to the plane of the laser array 14. The laser light 16 propagates along the optical axis 24. The optical axis 24 runs centered through the laser array 14 and can coincide with a symmetry axis of the laser array 14 and/or the optical axes of the optics elements 21, 22, 23. The laser light 16 superimposes at the latest after passing through all optics elements 21, 22, 23 in order to obtain a homogeneous light intensity in the far field transverse to the optical axis 21, 22, 23.

The laser light 16, which emerges from the optics device 19, comprises a cross-section aligned perpendicular to the optical axis 24, which can in particular be rectangular. The laser device 10 can in particular be provided for camera applications, wherein the field of view of a camera can be illuminated by the laser light 16.

To ensure that the laser device 10 complies with laser safety regulations, it is provided that the cross-section through the emitted laser light 16 in the beam-shaping optics element that provides the new apparent source comprises a two to five times greater side length than the laser array.

FIG. 1 shows a laser device 10 whose optics device 19 comprises a first, a second and a third optics element 21, 22, 23.

The first optics element 21 is provided for expanding the laser light 16 emitted from the semiconductor lasers 18, wherein the first optics element 21 is configured purely by way of example as a refractive scattering lens. A concave surface of the scattering lens can face the laser array 14. The first optics element 21 covers the entire laser array 14. In particular, the concave surface completely covers the entire laser array 14 of the semiconductor component 12, such that the entire emitted laser light 16 is expanded by the scattering lens. The first optics element 21 expands the laser light 16 to an angle that is greater than the divergence of the lasers. As a result, the cross-section of the entire laser light 16 can be enlarged after a shorter distance than would be possible without the first optics element 21.

The second optics element 22 is provided for collimating the laser light 16, which has been expanded by the first optics element 21. The first optics element 21 is arranged between the laser array 14 and the second optics element 22. Exemplarily, the second optics element 22 is a collimating (converging) lens. The collimating lens generates a half-maximum (half-value) angle of the laser light 16 of at most 10°, which approximately represents the original angle of divergence of the laser light 16, which has not been altered by optics elements. Preferably, the divergence after the second optics element 22 is significantly smaller than the original divergence of the laser 14, so that the third optics element 23 can shape the beam better and the final beam profile is less smeared out by different input angles into the optics 23.

The third optics element 23 is provided for shaping the laser light 16. For example, the beam profile of the laser light 16 can be homogenized by a scattering effect as in a diffuser when passing through the third optics element 23.

Alternatively or in addition, such homogenization can be achieved by superimposing the laser light 16 of different semiconductor lasers 18 of the laser array 14. Hereby, the third optics element 23 comprises a lens array of refractive lenses. Hereby each of the individual lenses of the lens array illuminates the entire camera field of view or at least a large part of it, so that each region of the camera field of view is illuminated from many points within the illuminated area of the optics 23 and thus provides a new apparent source according to IEC 60825-1:2014.

Preferably, the third optics element 23 shapes the laser light 16 such that it comprises a rectangular cross-section aligned transversely to the optical axis 24. The cross-section can comprise square sides or sides of different lengths. The half-maximum angle can be approximately 45° along a first direction and approximately 70° along a second direction.

What is important here for improving laser safety is that the optics element 23 for each angle of the desired beam profile in the far field deflects the laser light at many different points within the illuminated cross-section in the optics element 23. Ideally, the entire illuminated area in the element 23 shines into each angular region of the desired beam profile, as outlined in FIG. 1. Each of the three laser beams from the three illustrated lasers is split into many partial beams (scattered, diffracted or refracted) in element 23. A fictitious observer looking at the optics element 23 for example from below, who can only receive the downwardly deflected beams, sees the entire illuminated cross-section illuminated and has the same apparent source size as an observer looking along the optical axis or from upwardly.

An illuminated area 34 at the third optics element 23 comprises sides two to five times longer than the laser array 14. The illuminated area 34 provides the decisive area for compliance with the laser safety regulations. Hereby, the illuminated area 34 is the area on the third optics element 23 on which the laser light 16 strikes after it passes through the upstream optics elements 21, 22.

The third optics element 23 can be configured as a lens array. Thereby, a plurality of refractive lenses is arranged on a side of the third optics element 23.

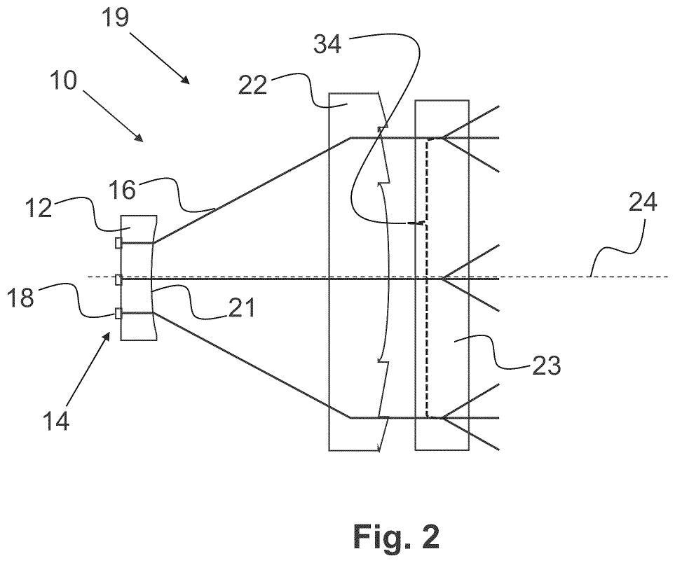

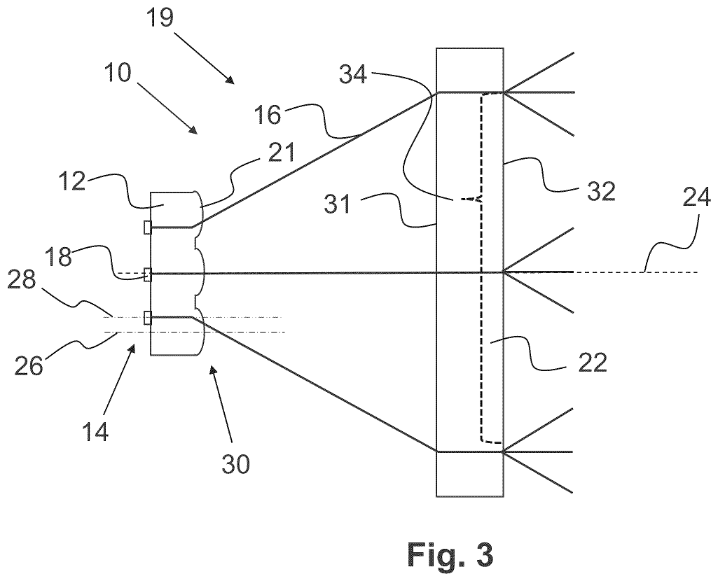

The above explanations with regard to the third optics element 23 can be applied to the embodiments shown in FIGS. 2 and 3.

FIG. 2 shows a laser device 10 comprising a first optics element 21 configured integrally with the semiconductor component 12. The first optics element 21 can comprise a refractive lens, a diffractive element and/or an optics element comprising an optical metamaterial. The first optics element 21 can be made from a semiconductor material. Alternatively or in addition, also further dielectric and/or transparent materials can be used for the first optics element 21.

The second optics element 22 is configured exemplarily as a Fresnel lens, which collimates the laser light 16.

FIG. 3 shows a laser device comprising an optics device 19 comprising only a first and a second optics element 21, 22.

The first optics element 21 comprises a lens array 30 of refractive lenses, wherein each of the lenses is associated with a single semiconductor laser 14. The lenses shown in FIG. 3 comprise symmetry axes 26 which are offset with respect to normal axes 28 of the individual semiconductor lasers 18. The normal axes 28 are located at a center of an emission region of the respective semiconductor laser 18. The laser light 16 is emitted from the emission region, wherein the emission region faces the optics device 19. The symmetry axes 26 and the normal axes 28 are oriented parallel to the optics axis 24. The laser light 16 propagates along the normal axis 28 from the emission area, wherein a respective light cone is provided symmetrically around the normal axis 28. The normal axes 28 are oriented perpendicular to a respective surface of the semiconductor laser 18.

The second optics element 22 comprises a first side 31 facing the semiconductor device 12 and a second side 32 facing away from the semiconductor device 32. The second optics element 22 comprises on the first side an element portion for collimating and on the second side 32 an element portion for shaping the laser light.

The element portion on the first and second sides 31, 32 can be configured in the same way as the optics elements 21, 22, 23 of the preceding embodiments.

Each of the described optics elements 21, 22, 23 can comprise diffractive optical elements and/or optics elements comprising an optical metamaterial.

It is also conceivable to combine the Fresnel lens from FIG. 2 with a first optics element 21 from FIG. 1 and/or FIG. 3.

The lens arrays of the first, the second and/or the third optics element 21, 22, 23 can comprise lenses, wherein the distances between symmetry axes of neighboring lenses are equal.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A laser device comprising:
a semiconductor laser component comprising a laser array, the laser array comprising a plurality of semiconductor lasers emitting a laser light vertically, and
an optics device comprising at least a second optics element and a first optics element arranged between the second optics element and the laser array along an optical axis, wherein the optics device is configured for expanding the laser light emitted from the semiconductor lasers, collimating the expanded laser light, and shaping a beam profile of the collimated laser light.

2. The laser device according to claim 1, wherein the laser light emanating from at least two locations of an illuminated area, generated by the laser light at an optics element of the optics device provided for shaping, is directed onto at least one solid angle range of the illuminated area outside the optics device, such that conditions of a standard IEC 60825-1:2014 4.3.d are fulfilled for all solid angles.

3. The laser device according to claim 1, wherein the first optics element comprises a scattering lens, which with respect to the optical axis of the laser light completely covers the entire laser array of the semiconductor component.

4. The laser device according to claim 1, wherein the first optics element is configured to expand the laser light such that a half-maximum angle of the laser light of a semiconductor laser is more than 10°.

5. The laser device according to claim 1, wherein the first optics element is formed integrally with the semiconductor component.

6. The laser device according to claim 1, wherein the first optics element comprises a lens array of refractive lenses, each refractive lens associated with a respective semiconductor laser, each refractive lens comprising a symmetry axis, which is offset with respect to a normal axis of the respective semiconductor laser, wherein the symmetry axis and the normal axis are oriented parallel to the optical axis.

7. The laser device according to claim 1, wherein the second optics element comprises a collimating lens configured to generate a half-maximum angle of the laser light of at most 10°.

8. The laser device according to claim 1, wherein the second optics element comprises a Fresnel lens, a diffractive optical element, and/or an optics element comprising an optical metamaterial.

9. The laser device according to claim 1, wherein the second optics element comprises a first element portion for collimating the laser light, and a second element portion for shaping the laser light on a common side.

10. The laser device according to claim 1, wherein the second optics element comprises a first element portion on a first side for collimating the laser light, and a second element portion on a second side for shaping the laser light.

11. The laser device according to claim 1, wherein the optics device comprises a third optics element, configured for shaping the collimated laser light, wherein the second optics element is configured for collimating the laser light.

12. The laser device according to claim 11, wherein an illuminated area at the third optics element has a side length that is two to five times greater than a length of the laser array.

13. The laser device according to claim 11, wherein the third optics element is configured to shape the laser light such that the laser light has a rectangular cross-section aligned transversely to the optical axis.

14. The laser device according to claim 11, wherein the third optics element comprises a lens array, at least one diffractive optical element, and/or an optics element comprising an optical metamaterial.

15. The laser device according to claim 11, wherein a cross-section of the laser light aligned perpendicular to the optics axis at a distance of at least one millimeter after the optics device has a side length that is two to five times greater than a length of the laser array.
